(19) United States
(12) Patent Application Publication
(10) Pub. No.: US 2024/0321641 A1
(43) Pub. Date: Sep. 26, 2024

(54) FABRICATION OF HIGH ASPECT RATIO ELECTRONIC DEVICES WITH MINIMAL SIDEWALL SPACER LOSS

(71) Applicant: Applied Materials, Inc., Santa Clara, CA (US)

(72) Inventors: Hao Jiang, San Jose, CA (US); Jong Mun Kim, San Jose, CA (US); Jonathan Qian, San Jose, CA (US); He Ren, San Jose, CA (US); Mehul Naik, San Jose, CA (US)

(21) Appl. No.: 18/606,739

(22) Filed: Mar. 15, 2024

Related U.S. Application Data
(60) Provisional application No. 63/454,495, filed on Mar. 24, 2023.

(51) Int. Cl. H01L 21/822; H01L 21/311

(52) U.S. Cl. CPC H01L 21/8221; H01L 21/31116

(57) ABSTRACT

A method includes forming a planarization layer to a position below an upper transistor device region of a base structure of an electronic device and above a lower transistor device region of the base structure. The base structure includes a plurality of features. The method further includes forming spacer material along the base structure and the planarization layer, modifying the spacer material formed along bottom trenches of the base structure to obtain modified spacer material, and forming a spacer layer by using a wet etch process to remove the modified spacer material. Modifying the spacer material formed along the bottom trenches of the base structure to obtain the modified spacer material includes performing a dry etch process targeting the spacer material formed along the bottom trenches of the base structure.

### CROSS-REFERENCE TO RELATED APPLICATION(S)

The present application claims the benefit of U.S. Provisional Application No. 63/454,495, filed on Mar. 24, 2023 and entitled “FABRICATION OF HIGH ASPECT RATIO ELECTRONIC DEVICES WITH MINIMAL SIDEWALL SPACER LOSS”, the entire contents of which are incorporated by reference herein.

### TECHNICAL FIELD

Embodiments of the present disclosure generally relate to electronic device fabrication. Particularly, embodiments of the present disclosure relate to fabrication of high aspect ratio electronic devices with minimal sidewall spacer loss.

### BACKGROUND

An electronic device manufacturing apparatus can include multiple chambers, such as process chambers and load lock chambers. Such an electronic device manufacturing apparatus can employ a robot apparatus in transfer chamber that is configured to transport substrates between the multiple chambers. In some instances, multiple substrates are transferred together. Process chambers may be used in an electronic device manufacturing apparatus to perform one or more processes on substrates, such as deposition processes and etch processes. For many processes gasses are flowed into the process chamber. Electronic devices, such as semiconductor devices, are manufactured by performing a series of operations that may include deposition, oxidation, photolithography, ion implantation, etch, and so on to form many patterned layers.

### SUMMARY

In accordance with an embodiment, a method is provided. The method includes forming a planarization layer to a position below an upper transistor device region of a base structure of an electronic device and above a lower transistor device region of the base structure. The base structure includes a plurality of features. The method further includes forming spacer material along the base structure and the planarization layer, modifying the spacer material formed along bottom trenches of the base structure to obtain modified spacer material, and forming a spacer layer by using a wet etch process to remove the modified spacer material. Modifying the spacer material formed along the bottom trenches of the base structure to obtain the modified spacer material includes performing a dry etch process targeting the spacer material formed along the bottom trenches of the base structure.

In accordance with another embodiment, a method is provided. The method includes obtaining a base structure of an electronic device including a plurality of features and having an upper transistor device region and a lower transistor device region, forming, from the base structure, a planarization layer to a position below the upper transistor device region and above the lower transistor device region, forming spacer material along the base structure and the planarization layer, modifying the spacer material formed along bottom trenches of the base structure to obtain modified spacer material, forming a spacer layer by using a wet etch process to remove the modified spacer material, removing the planarization layer, forming a set of epitaxial layers within the lower transistor device region, and removing the spacer layer. Modifying the spacer material formed along the bottom trenches of the base structure to obtain the modified spacer material includes performing a dry etch process targeting the spacer material formed along the bottom trenches of the base structure.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIGS. 1A-1D are cross-sectional views illustrating an example method of fabricating an electronic device, in accordance with some embodiments.

FIGS. 2A-2F are perspective views illustrating an example method of fabricating an electronic device, in accordance with some embodiments.

FIG. 3 is a flowchart of an example method of fabricating an electronic device, in accordance with some embodiments.

### DETAILED DESCRIPTION

Embodiments described herein relate to fabrication of electronic devices with minimal sidewall spacer loss. Some electronic devices can include one or more transistors. Examples of transistors include field-effect transistors (FETs). Spacers can be used during the fabrication of some electronic devices. For example, spacers can be formed to protect sidewalls of an electronic device while exposing a bottom portion of a device during processing (e.g., the bottom of a trench). More specifically, spacer material can be formed on sidewalls of a feature and a bottom surfaces of the feature, and the portion of the spacer material formed on the bottom surfaces of the feature can be removed to expose the bottom portion.

Some spacers are etched using a dry etch process, such as reactive-ion etching (RIE). However, the radicals and deflected ions generated during the dry etch process can damage the sidewall spacer material. This can be particularly pronounced as the distances between adjacent features shrink (e.g., “critical dimensions”) and corresponding aspect ratios increase in accordance with more advanced technology nodes. An aspect ratio for a feature can be defined as the ratio between the height or depth of the feature and the critical dimension. This difficulty can be compounded by the formation of very thin spacers (e.g., less than or equal to about 3 nanometers (nm)) on feature sidewalls. Accordingly, due to radicals and/or deflected ions generated during dry etch processes (e.g., RIE), it is becoming increasing challenging to use such dry etch processes to remove bottom spacer material to fabricate high aspect ratio electronic devices while maintaining the thickness of the spacer material formed on feature sidewalls.

To address these and other drawbacks, embodiments described herein can be used to fabricate electronic devices with minimal sidewall spacer loss. Fabricating an electronic device can include obtaining a base structure including an upper transistor device region and a lower transistor region. For example, obtaining the base structure can include forming the base structure.

The base structure can include a plurality of features. Each feature can have a substantially same height or depth, and a pair of features can be separated by a substantially same critical dimension. In some embodiments, an electronic device is a high aspect ratio electronic device. More specifically, a high aspect ratio electronic device is an electronic device that includes features having a high aspect ratio with respect to feature height or depth, and critical dimension. In some embodiments, a high aspect ratio is an aspect ratio greater than or equal to about 8:1. In some embodiments, a high aspect ratio is an aspect ratio greater than or equal to about 10:1. In some embodiments, a high aspect ratio is an aspect ratio greater than or equal to about 15:1. In some embodiments, a high aspect ratio is an aspect ratio greater than or equal to about 20:1. In some embodiments, the critical dimension ranges from about 10 nm to about 30 nm. In some embodiments, the critical dimension ranges from about 15 nm to about 20 nm.

In some embodiments, the electronic device includes a three-dimensional (3D) transistor device. In some embodiments, a 3D transistor device is a 3D complementary metal-oxide semiconductor (CMOS) device. A CMOS device includes a first transistor device having a first type and a second transistor device having a second type complementary to the first type. For example, a CMOS device can include an n-type metal-oxide semiconductor (NMOS) transistor device and a p-type metal-oxide semiconductor (PMOS) transistor device. In some embodiments, an NMOS transistor device is an n-type FET (nFET) that includes source/drain regions formed from n-type doped semiconductor material and a substrate formed from a p-type doped semiconductor material. In some embodiments, a PMOS transistor device is a p-type FET (pFET) that includes source/drain regions formed from p-type doped semiconductor material and a substrate formed from an n-type doped semiconductor material. In some embodiments, a 3D transistor device is a complementary FET (cFET) device. A cFET device includes an upper FET having a first type vertically stacked on a lower FET having a second type complementary to the first type, where the upper FET and the lower FET share a gate structure. For example, the upper FET can be an nFET and the lower FET can be pFET. As another example, the upper FET can be a pFET and the lower FET can be an nFET. The upper FET and the lower FET can be separated by an insulator layer. In some embodiments, the upper FET includes a first nanowire and the lower FET includes a second nanowire.

Fabricating the electronic device can further include forming a planarization layer. More specifically, the planarization layer can be formed to a position above the lower transistor device region and below the upper transistor device region. For example, the planarization layer can be formed to a position adjacent to the insulator layer. Forming the planarization layer can include forming planarization layer material to some height above the upper transistor device region, and recessing the planarization layer material to the position below the upper transistor device region (e.g., the position adjacent to the insulator layer). In some embodiments, the planarization layer includes a carbon (C) material (e.g., amorphous carbon material). The planarization layer material can be formed using any suitable process. For example, the planarization layer can include a spin-on carbon (SoC) material. In some embodiments, recessing the planarization layer material includes performing a diimide or diazene (H₂N₂) recess.

Fabricating the electronic device can further include forming a spacer layer on a base structure. More specifically, forming the spacer layer can include conformally depositing spacer material along the upper transistor device region up to the planarization layer. The spacer material can uniformly cover sidewalls of the plurality of features, as well as the bottom of trenches of the base structure. In some embodiments, the spacer material is conformally deposited using atomic layer deposition (ALD).

The spacer material can include any suitable dielectric material in accordance with embodiments described herein. In some embodiments, the spacer material includes a silicon (Si)-based material. For example, the spacer material can include a silicon nitride material. Examples of silicon nitride materials include silicon nitride (SiₓN_{y}), silicon oxynitride (SiON), silicon oxycarbonitride (SiOCN), etc. The spacer material can be formed to have any suitable thickness. In some embodiments, the spacer layer has a thickness between about 2 nm to about 8 nm. In some embodiments, the spacer layer has a thickness between about 3 nm to about 6 nm.

Fabricating the electronic device can further include performing a two-step etch process to remove the spacer material formed along the bottom surfaces of the trenches. The two-step etch process can include a first step in which the spacer material formed along the bottom surfaces of the trenches is damaged, with minimal damage to the spacer material formed along the feature sidewalls, and a second step in which the spacer material formed along the bottom surfaces of the trenches are removed while minimizing the loss of the spacer material formed along the feature sidewalls.

More specifically, performing the two-step etch process can include modifying the spacer material formed along the bottom surfaces of the trenches. In some embodiments, modifying the spacer material formed along the bottom surfaces of the trenches can include employing a dry etch process using a plasma etchant. For example, the dry etch process can be an ion bombardment process. The directional and energetic ions can bombard the spacer material formed along the bottom surfaces of the trenches, which damages the spacer material formed along the bottom surfaces of the trenches. Damage can include physical damage caused by the ion bombardment and/or chemical damage caused by the plasma. Due to the directionality of the ion bombardment with respect to the bottom surfaces of the trenches, spacer material formed along the feature sidewalls can suffer relatively low damage. Any suitable plasma etchant that is non-reactive relative to the spacer material can be used to perform the dry etch process. For example, the plasma etchant can include one or more non-reactive or inert gas species such as noble gases (e.g., helium (He), neon (Ne), argon (Ar), krypton (Kr) and/or xenon (Xe)), nitrogen gas (N₂), etc.

Performing the two-step etch process can further include employing a wet etch process to remove the damaged spacer material along the bottom surfaces of the trenches. In this step, the electronic device is submerged into a wet etchant for an amount of time. The damage caused to the spacer material along the bottom surfaces of the trenches increases the selectivity of the wet etch relative to the spacer material along the feature sidewalls, such that only a minimal amount of the spacer material along the feature sidewalls will be removed within the amount of time that the electronic device is submerged within the wet etchant. Any suitable wet etchant can be used to perform the wet etch process in accordance with embodiments described herein. In some embodiments, the wet etchant includes dilute hydrofluoric acid (dHF). For example, the dHF can have a ratio of greater than or equal to 100:1 and the electronic device can be submerged for about 60 seconds. Accordingly, the spacer layer is formed after employing the wet etch process to remove the spacer material from the bottom surfaces of the trenches.

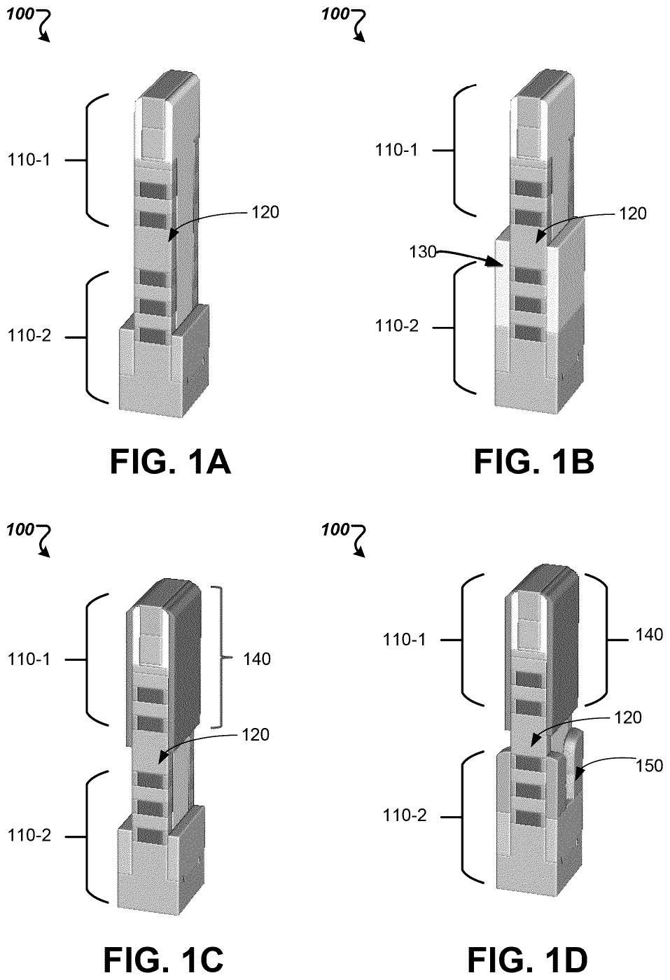

Fabricating the electronic device can further include removing the planarization layer and forming epitaxial layers within the lower transistor device region. More specifically, the spacer material along the feature sidewalls function to block the formation of the epitaxial layers on the upper transistor device region. After forming the epitaxial layers within the lower transistor device region, the remaining spacer material can be removed from the electronic device and further device processing can be performed. Further details regarding fabricating electronic devices with minimal sidewall spacer loss will be described below with reference to FIGS. 1A-3.

FIGS. 1A-1D are cross-sectional views illustrating an example method of fabricating an electronic device (“device”) 100, in accordance with some embodiments. For example, FIG. 1A shows a step of obtaining a base structure of device 100. More specifically, device 100 can be a 3D CMOS device and the base structure can include upper transistor device region 110-1 corresponding to an upper transistor device having a first type, and lower transistor device region 110-2 corresponding to a lower transistor device having a second type complementary to the first type. As shown, upper transistor device region 110-1 and lower transistor device region 110-2 can be separated by insulator layer 120. In some embodiments, upper transistor device region 110-1 corresponds to an NMOS transistor device and lower transistor device region 110-2 corresponds to a PMOS transistor device. In some embodiments, upper transistor device region 110-1 corresponds to a PMOS transistor device and lower transistor device region 110-2 corresponds to an NMOS transistor device. In some embodiments, device 100 includes a cFET device, where the NMOS transistor device is an nFET and the PMOS transistor device is a pFET. In some embodiments, upper transistor device region 110-1 includes a first nanowire and lower transistor device region 110-2 includes a second nanowire. In some embodiments, obtaining the base structure includes forming the base structure.

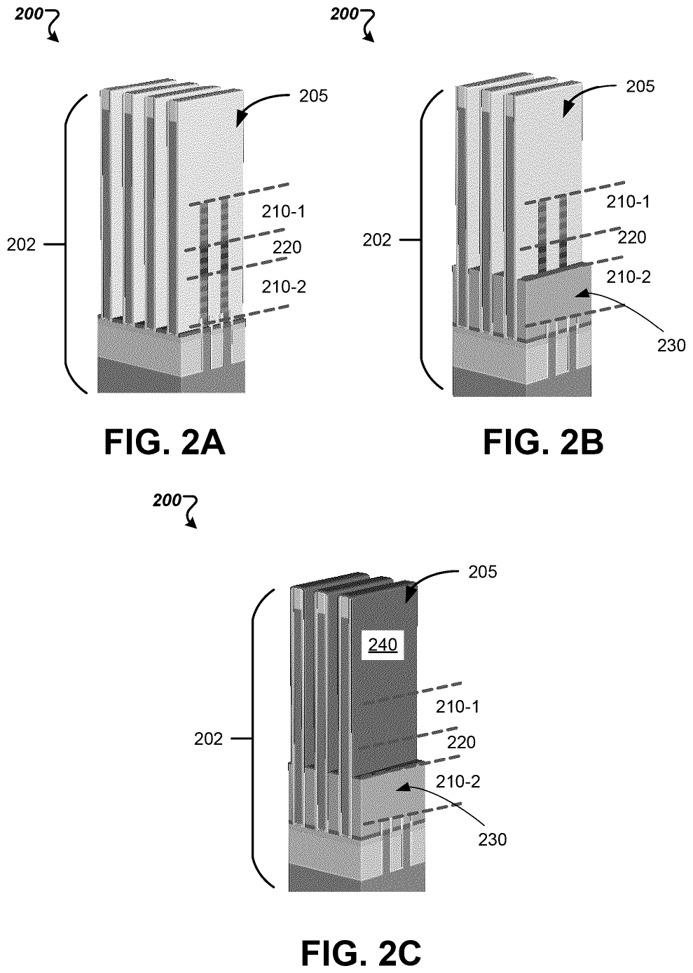

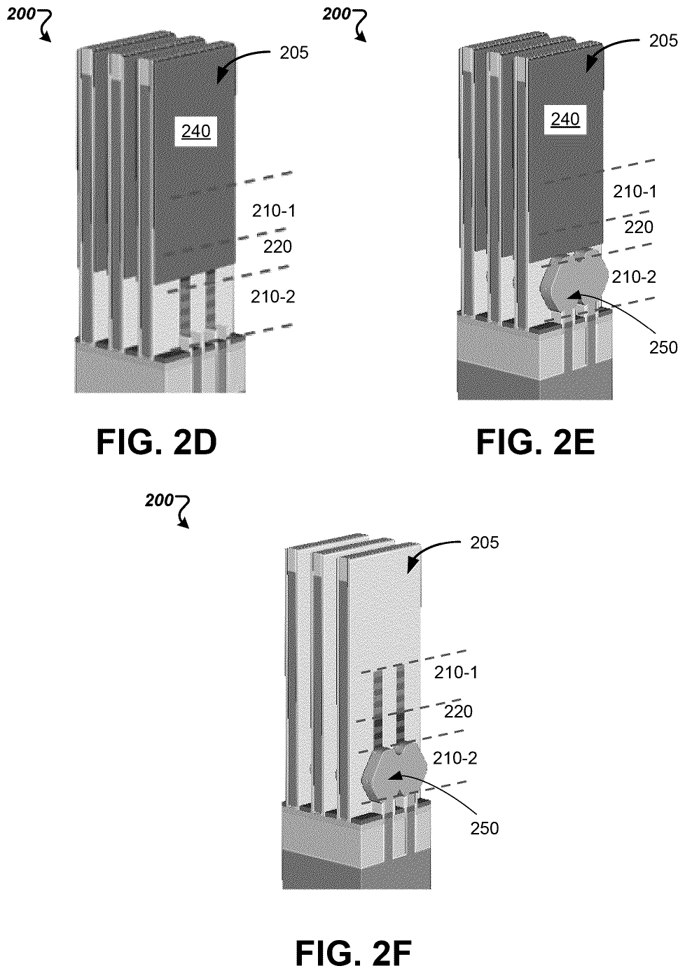

As will be described in further detail below with reference to FIG. 2, the base structure can include a plurality of features. Each feature can have a substantially same height or depth, and a pair of features can be separated by a substantially same critical dimension. In some embodiments, device 100 is a high aspect ratio electronic device. More specifically, each feature can have a high aspect ratio with respect to feature height or depth, and critical dimension. In some embodiments, a high aspect ratio is an aspect ratio greater than or equal to about 8:1. In some embodiments, a high aspect ratio is an aspect ratio greater than or equal to about 10:1. In some embodiments, a high aspect ratio is an aspect ratio greater than or equal to about 15:1. In some embodiments, a high aspect ratio is an aspect ratio greater than or equal to about 20:1. In some embodiments, the critical dimension ranges from about 10 nm to about 30 nm. In some embodiments, the critical dimension ranges from about 15 nm to about 20 nm.

FIG. 1B illustrates a step of forming planarization layer 130 to a position below upper transistor device region 110-1 and above lower transistor device region 110-2. More specifically, planarization layer 130 can be formed to a position adjacent to insulator layer 120. Forming planarization layer 130 can include forming planarization layer material to some height above upper transistor device region 110-1, and recessing the planarization layer material to the position below upper transistor device region 110-1 and above lower transistor device region 110-2 (e.g., the position adjacent to insulator layer 120). In some embodiments, planarization layer 130 includes a carbon (C) material. The planarization layer material can be formed using any suitable process. For example, planarization layer 130 can include an SoC material. In some embodiments, recessing the planarization layer material includes performing a diimide or diazene (H₂N₂) recess.

FIG. 1C illustrates a step of forming spacer layer 140 on the base structure. More specifically, forming spacer layer 140 can include conformally depositing spacer material along upper transistor device region 110-1 up to planarization layer 120. The spacer material can uniformly cover sidewalls of the plurality of features, as well as the bottom of trenches of the base structure. In some embodiments, the spacer material is conformally deposited using ALD.

The spacer material can include any suitable dielectric material in accordance with embodiments described herein. In some embodiments, the spacer material includes a silicon (Si)-based material. For example, the spacer material can include a silicon nitride material. Examples of silicon nitride materials include silicon nitride (SiₓN_{y}), silicon oxynitride (SiON), silicon oxycarbonitride (SiOCN), etc. The spacer material can be formed to have any suitable thickness. In some embodiments, the spacer material is formed to have a thickness between about 2 nm to about 8 nm. In some embodiments, the spacer material is formed to have a thickness between about 3 nm to about 6 nm.

Forming spacer layer 140 can further include modifying the portions of the spacer material formed along the bottom surfaces of the trenches of the base structure. In some embodiments, modifying the portions of the spacer material formed along the bottom surfaces of the trenches can include employing a dry etch process using a plasma etchant. For example, the dry etch process can be an ion bombardment process. The directional and energetic ions can bombard the spacer material formed along the bottom surfaces of the trenches, which damages the portions of the spacer material formed along the bottom surfaces of the trenches. Damage can include physical damage caused by the ion bombardment and/or chemical damage caused by the plasma. Due to the directionality of the ion bombardment with respect to the bottom surfaces of the trenches, portions of the spacer material formed along the feature sidewalls can suffer relatively low damage. Any suitable plasma etchant that is non-reactive relative to the spacer material can be used to perform the dry etch process. For example, the plasma etchant can include one or more non-reactive or inert gas species such as noble gases (e.g., He, Ne, Ar, Kr, Xe), N₂, etc.

Forming spacer layer 140 can further include employing a wet etch process to remove the damaged spacer material along the bottom surfaces of the trenches. In this step, device 100 is submerged into a wet etchant for an amount of time. The damage caused to the spacer material along the bottom surfaces of the trenches increases the selectivity of the wet etch relative to the spacer material formed along the feature sidewalls, such that only a minimal amount of the spacer material formed along the feature sidewalls will be removed within the amount of time that the electronic device is submerged within the wet etchant. Any suitable wet etchant can be used to perform the wet etch process in accordance with embodiments described herein. In some embodiments, the wet etchant includes dHF. For example, the dHF can have a ratio of at least 100:1 and the electronic device can be submerged for about 60 seconds. Accordingly, spacer layer 140 is formed after employing the wet etch process to remove the spacer material from the bottom surfaces of the trenches of the base structure.

As further shown, planarization layer 120 can be removed after forming spacer layer 140. Planarization layer 120 can be removed using any suitable process in accordance with embodiments described herein. In some embodiments, planarization layer 120 is removed using a plasma etch process. For example, if planarization layer 120 includes a carbon material, then a hydrogen gas (H₂)/N₂ plasma can be used to remove planarization layer 120.

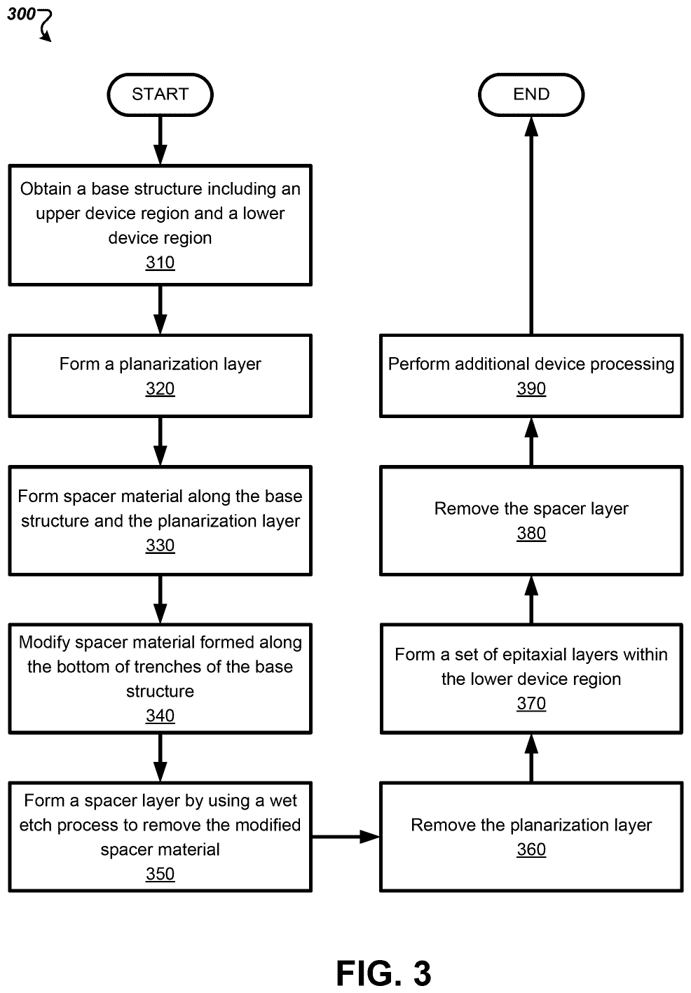

FIG. 1D illustrates a step of forming epitaxial layers 150 within bottom transistor device region 110-2. More specifically, the portions of spacer layer 140 along the feature sidewalls function to block the formation of epitaxial layers 150 within upper transistor device region 110-1. After forming epitaxial layers 150 within lower transistor device region 110-2, the remaining portions of spacer layer 140 can be removed from the electronic device and further device processing can be performed to complete fabrication of device 100. Further details regarding fabricating device 100 will now be described below with reference to FIGS. 2-3.

FIGS. 2A-2F are perspective views illustrating an example method of fabricating an electronic device (“device”) 200, in accordance with some embodiments. For example, FIG. 2A shows a step of obtaining base structure 202. More specifically, device 100 can be a three-3D CMOS device and base structure 202 can include upper transistor device region 210-1 corresponding to a first transistor device having a first type, and lower transistor device region 210-2 corresponding to a second transistor device having a second type complementary to the first type. As shown, upper transistor device region 210-1 and lower transistor device region 210-2 can be separated by insulator layer 220. In some embodiments, upper transistor device region 210-1 corresponds to an NMOS transistor device and lower transistor device region 210-2 corresponds to a PMOS transistor device. In some embodiments, upper transistor device region 210-1 corresponds to a PMOS transistor device and lower transistor device region 210-2 corresponds to an NMOS transistor device. In some embodiments, device 200 includes a cFET device, where the NMOS transistor device is an nFET and the PMOS transistor device is a pFET. In some embodiments, upper transistor device region 210-1 includes a first nanowire and lower transistor device region 210-2 includes a second nanowire. In some embodiments, obtaining the base structure includes forming base structure 202.

Base structure 202 can include a plurality of features including feature 205. Each feature can have a substantially same height or depth, and a pair of features can be separated by a substantially same critical dimension. In some embodiments, device 200 is a high aspect ratio electronic device. More specifically, each feature can have a high aspect ratio with respect to feature height or depth, and critical dimension. In some embodiments, a high aspect ratio is an aspect ratio greater than or equal to about 8:1. In some embodiments, a high aspect ratio is an aspect ratio greater than or equal to about 10:1. In some embodiments, a high aspect ratio is an aspect ratio greater than or equal to about 15:1. In some embodiments, a high aspect ratio is an aspect ratio greater than or equal to about 20:1. In some embodiments, the critical dimension ranges from about 10 nm to about 30 nm. In some embodiments, the critical dimension ranges from about 15 nm to about 20 nm.

FIG. 2B illustrates a step of forming planarization layer 230 to a position below upper transistor device region 210-1 and above lower transistor device region 210-2. More specifically, planarization layer 230 can be formed to a position adjacent to insulator layer 220. Forming planarization layer 230 can include forming planarization layer material to some height above upper transistor device region 210-1, and recessing the planarization layer material to the position below upper transistor device region 210-1 and above lower transistor device region 210-2 (e.g., the position adjacent to insulator layer 220). In some embodiments, planarization layer 230 includes a carbon (C) material. The planarization layer material can be formed using any suitable process. For example, planarization layer 230 can include an SoC material. In some embodiments, recessing the planarization layer material includes performing a diimide or diazene (H₂N₂) recess.

FIG. 2C illustrates a step of forming spacer layer 240 on base structure 202 and planarization layer 220. More specifically, forming spacer layer 240 can include conformally depositing spacer material along upper transistor device region 210-1 up to planarization layer 220. The spacer material can uniformly cover sidewalls of the plurality of features including feature 205, as well as the bottom of trenches of base structure 202. In some embodiments, the spacer material is conformally deposited using ALD.

The spacer material can include any suitable dielectric material in accordance with embodiments described herein. In some embodiments, the spacer material includes a silicon (Si)-based material. For example, the spacer material can include a silicon nitride material. Examples of silicon nitride materials include silicon nitride (SiₓN_{y}), silicon oxynitride (SiON), silicon oxycarbonitride (SiOCN), etc. The spacer material can be formed to have any suitable thickness. In some embodiments, the spacer material is formed to have a thickness between about 2 nm to about 8 nm. In some embodiments, the spacer material is formed to have a thickness between about 3 nm to about 6 nm.

Forming spacer layer 240 can further include modifying the portions of the spacer material formed along the bottom surfaces of the trenches of the base structure. In some embodiments, modifying the portions of the spacer material formed along the bottom surfaces of the trenches can include employing a dry etch process using a plasma etchant. For example, the dry etch process can be an ion bombardment process. The directional and energetic ions can bombard the spacer material formed along the bottom surfaces of the trenches, which damages the portions of the spacer material formed along the bottom surfaces of the trenches. Damage can include physical damage caused by the ion bombardment and/or chemical damage caused by the plasma. Due to the directionality of the ion bombardment with respect to the bottom surfaces of the trenches, portions of the spacer material formed along the feature sidewalls can suffer relatively low damage. Any suitable plasma etchant that is non-reactive relative to the spacer material can be used to perform the dry etch process. For example, the plasma etchant can include one or more non-reactive or inert gas species such as noble gases (e.g., He, Ne, Ar, Kr and/or Xe), N₂, etc.

Forming spacer layer 240 can further include employing a wet etch process to remove the damaged spacer material along the bottom surfaces of the trenches. In this step, device 200 is submerged into a wet etchant for an amount of time. The damage caused to the spacer material along the bottom surfaces of the trenches increases the selectivity of the wet etch relative to the spacer material formed along the feature sidewalls, such that only a minimal amount of the spacer material formed along the feature sidewalls will be removed within the amount of time that the electronic device is submerged within the wet etchant. Any suitable wet etchant can be used to perform the wet etch process in accordance with embodiments described herein. In some embodiments, the wet etchant includes dHF. For example, the dHF can have a ratio of at least 100:1 and the electronic device can be submerged for about 60 seconds. Accordingly, spacer layer 240 is formed after employing the wet etch process to remove the spacer material from the bottom surfaces of the trenches of the base structure.

FIG. 2D illustrates a step of removing planarization layer 220 after forming spacer layer 240. Planarization layer 220 can be removed using any suitable process in accordance with embodiments described herein. In some embodiments, planarization layer 220 is removed using a plasma etch process. For example, if planarization layer 220 includes a carbon material, then an H₂/N₂ plasma can be used to remove planarization layer 220.

FIG. 2E illustrates a step of forming epitaxial layers 250 within bottom transistor device region 210-2. More specifically, the portions of spacer layer 240 along the feature sidewalls function to block the formation of epitaxial layers 250 within upper transistor device region 210-1.

FIG. 2F illustrates a step for removing the remaining portions of spacer layer 240 after forming epitaxial layers 250 within lower transistor device region 210-2. In some embodiments, removing the remaining portions of spacer layer 240 includes performing a wet etch process. For example, the wet etch process can be a hot phosphoric acid (H₃PO₄) etch process, which can be selective to a silicon oxide material. As another example, the wet etch process can be a dHF etch process, which can be selective to a silicon nitride material. In some embodiments, removing the remaining portions of spacer layer 240 includes performing a dry etch process (e.g., plasma etch process). The dry etchant used can depend on the material of spacer layer 240. Further device processing can then be performed to complete fabrication of device 200. Further details regarding fabricating device 200 are described above with reference to FIG. 2 and will now be described below with reference to FIG. 3.

FIG. 3 depicts an example method 300 of fabricating an electronic device using area-selective deposition, in accordance with some embodiments. Method 300 can be performed within an electronic device processing system. More specifically, method 300 can be performed within one or more process chambers of the electronic device processing system.

At step 310, a base structure including an upper device region and a lower device region is obtained. For example, the upper device region and the lower device region can be separated by an insulator layer. In some embodiments, obtaining the base structure includes forming the base structure.

More specifically, the electronic device can be 3D CMOS device, the upper transistor device region can correspond to an upper transistor device having a first type, and the lower transistor device region can correspond to a lower transistor device having a second type complementary to the first type. In some embodiments, the upper transistor device is an NMOS transistor device and the lower transistor device is a PMOS transistor device. In some embodiments, the upper transistor device is a PMOS transistor device and the lower transistor device is an NMOS transistor device. In some embodiments, the electronic device is a cFET device, where the NMOS transistor device is an nFET and the PMOS transistor device is a pFET. In some embodiments, the upper transistor device region includes a first nanowire and the lower transistor device region includes a second nanowire.

The base structure can include a plurality of features. Each feature can have a substantially same height or depth, and a pair of features can be separated by a substantially same critical dimension. In some embodiments, an electronic device is a high aspect ratio electronic device. More specifically, a high aspect ratio electronic device is an electronic device that includes features having a high aspect ratio with respect to feature height or depth, and critical dimension. In some embodiments, a high aspect ratio is an aspect ratio greater than or equal to about 8:1. In some embodiments, a high aspect ratio is an aspect ratio greater than or equal to about 10:1. In some embodiments, a high aspect ratio is an aspect ratio greater than or equal to about 15:1. In some embodiments, a high aspect ratio is an aspect ratio greater than or equal to about 20:1. In some embodiments, the critical dimension ranges from about 10 nm to about 30 nm. In some embodiments, the critical dimension ranges from about 15 nm to about 20 nm.

At step 320, a planarization layer is formed. More specifically, the planarization layer can be formed to a position below the upper transistor device region and above the lower transistor device region. For example, the planarization layer can be formed to a position adjacent to the insulator layer. Forming the planarization layer can include forming planarization layer material to some height above the upper transistor device region, and recessing the planarization layer material to the position below the upper transistor device region (e.g., the position adjacent to the insulator layer. In some embodiments, the planarization layer includes a carbon (C) material. The planarization layer material can be formed using any suitable process. For example, the planarization layer can include an SoC material. In some embodiments, recessing the planarization layer material includes performing a diimide or diazene (H₂N₂) recess.

At step 330, spacer material is formed along the base structure and the planarization layer. More specifically, forming the spacer material along the base structure can include conformally depositing spacer material along the first transistor device region up to the planarization layer. The spacer material can uniformly cover sidewalls of the plurality of features, as well as the bottom of trenches of the base structure. In some embodiments, the spacer material is conformally deposited using ALD.

The spacer material can include any suitable dielectric material in accordance with embodiments described herein. In some embodiments, the spacer material includes a silicon (Si)-based material. For example, the spacer material can include a silicon nitride material. Examples of silicon nitride materials include silicon nitride (SiₓN_{y}), silicon oxynitride (SiON), silicon oxycarbonitride (SiOCN), etc. The spacer material can be formed to have any suitable thickness. In some embodiments, the spacer layer has a thickness between about 2 nm to about 8 nm. In some embodiments, the spacer layer has a thickness between about 3 nm to about 6 nm.

At step 340, spacer material formed along the bottom of trenches of the base structure is modified. More specifically, the spacer material formed along the bottom of the trenches of the base structure is damaged. To do so, a dry etch process is performed using a plasma etchant. More specifically, the dry etch process is a directional etch process that targets the spacer material formed along the bottom of the trenches of the base structure.

In some embodiments, the dry etch process is an ion bombardment process. The directional and energetic ions can bombard the spacer material formed along the bottom surfaces of the trenches, which damages the spacer material formed along the bottom surfaces of the trenches. Damage can include physical damage caused by the ion bombardment and/or chemical damage caused by the plasma. Due to the directionality of the ion bombardment with respect to the bottom surfaces of the trenches, spacer material formed along the feature sidewalls can suffer relatively low damage. Any suitable plasma etchant that is non-reactive relative to the spacer material can be used to perform the dry etch process. For example, the plasma etchant can include one or more non-reactive or inert gas species such as noble gases (e.g., He, Ne, Ar, Kr and/or Xe), N₂, etc.

As an illustrative example, an He/N₂ plasma treatment can be used using any suitable process parameters. Examples of process parameters include pressure, power (e.g., source power and bias power), gas flow, process time, etc. In some embodiments, the He/N₂ plasma treatment is performed at a pressure between about 1 mTorr to about 1 torr. In some embodiments, the He/N₂ plasma treatment is performed at a pressure between about 2 mTorr to about 10 mTorr. In some embodiments, the source power ranges from about 100 Watts (W) to about 500 W. In some embodiments, the source power ranges from about 200 W to about 400 W. In some embodiments, the source power ranges from about 250 W to about 350 W. In some embodiments, the bias power ranges from about 20 W to about 200 W. In some embodiments, the source power ranges from about 50 W to about 150 W. In some embodiments, the source power ranges from about 75 W to about 125 W. In some embodiments, the He/N₂ plasma treatment is performed with an He gas flow between about 10 standard cubic centimeters per minute (sccm) to about 500 sccm and an N₂ gas flow between about 10 sccm to about 500 sccm. In some embodiments, the He/N₂ plasma treatment is performed with an He gas flow between about 100 sscm to about 300 sccm and an N₂ gas flow between about 50 sccm to about 200 sccm. In some embodiments, the He/N₂ plasma treatment is performed with an He gas flow between about 175 sscm to about 215 sccm and an N₂ gas flow between about 75 sccm to about 150 sccm. In some embodiments, the process time is less than or equal to about 300 seconds. In some embodiments, the process time is less than or equal to about 240 seconds. In some embodiments, the process time is less than or equal to about 180 seconds. In some embodiments, the process time is less than or equal to about 120 seconds. In some embodiments, the process time is less than or equal to about 90 seconds. In some embodiments, the process time is less than or equal to about 80 seconds.

At step 350, a spacer layer is formed by using a wet etch process to remove the modified spacer material. More specifically, the electronic device is submerged into a wet etchant for an amount of time. The damage caused to the spacer material along the bottom surfaces of the trenches increases the selectivity of the wet etch relative to the spacer material along the feature sidewalls, such that only a minimal amount of the spacer material along the feature sidewalls will be removed within the amount of time that the electronic device is submerged within the wet etchant. Any suitable wet etchant can be used to perform the wet etch process in accordance with embodiments described herein. In some embodiments, the wet etchant includes dHF. For example, the dHF can have a ratio of greater than or equal to 100:1 and the electronic device can be submerged for about 60 seconds. Accordingly, the spacer layer is formed after employing the wet etch process to remove the spacer material from the bottom surfaces of the trenches.

At step 360, the planarization layer is removed. The planarization layer can be removed using any suitable process in accordance with embodiments described herein. In some embodiments, the planarization layer is removed using a plasma etch process. For example, if the planarization layer includes a carbon material, then an H₂/N₂ plasma can be used to remove the planarization layer.

At step 370, a set of epitaxial layers is formed within the lower device region. More specifically, the spacer layer functions to block the formation of the set of epitaxial layers within the lower device region.

At step 380, the spacer layer is removed.

At step 390, additional device processing is performed to complete fabrication of the electronic device.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
forming a planarization layer to a position below an upper transistor device region of a base structure of an electronic device and above a lower transistor device region of the base structure, wherein the base structure comprises a plurality of features;
forming spacer material along the base structure and the planarization layer;
modifying the spacer material formed along bottom trenches of the base structure to obtain modified spacer material, wherein modifying the spacer material formed along the bottom trenches of the base structure to obtain the modified spacer material comprises performing a dry etch process targeting the spacer material formed along the bottom trenches of the base structure; and
forming a spacer layer by using a wet etch process to remove the modified spacer material.

2. The method of claim 1, wherein forming the spacer material along the base structure and the planarization layer comprises conformally depositing the spacer material using an atomic layer deposition (ALD) process.

3. The method of claim 1, wherein the dry etch process is an ion bombardment process.

4. The method of claim 1, wherein forming the spacer layer by using the wet etch process to remove the modified spacer material comprises submerging the electronic device in dilute hydrofluoric acid (dHF).

5. The method of claim 1, wherein the plurality of features has an aspect ratio of greater than or equal to about 10:1.

6. The method of claim 1, wherein the plurality of features has an associated critical dimension between about 10 nanometers (nm) to about 30 nm.

7. The method of claim 6, wherein the plurality of features has an associated critical dimension between about 15 nm to about 20 nm.

8. The method of claim 1, further comprising:
removing the planarization layer after forming the spacer layer;
forming a set of epitaxial layers within the lower transistor device region; and
removing the spacer layer after forming the set of epitaxial layers.

9. The method of claim 1, wherein the spacer material comprises a silicon-based dielectric material.

10. The method of claim 1, wherein the electronic device comprises a three-dimensional (3D) transistor device.

11. The method of claim 10, wherein the electronic device comprises a complementary field-effect transistor (cFET) device.

12. A method comprising:
obtaining a base structure of an electronic device comprising a plurality of features and having an upper transistor device region and a lower transistor device region;
forming, from the base structure, a planarization layer to a position below the upper transistor device region and above the lower transistor device region;
forming spacer material along the base structure and the planarization layer;
modifying the spacer material formed along bottom trenches of the base structure to obtain modified spacer material, wherein modifying the spacer material formed along the bottom trenches of the base structure to obtain the modified spacer material comprises performing a dry etch process targeting the spacer material formed along the bottom trenches of the base structure;
forming a spacer layer by using a wet etch process to remove the modified spacer material;
removing the planarization layer;
forming a set of epitaxial layers within the lower transistor device region; and
removing the spacer layer.

13. The method of claim 12, wherein forming the spacer material along the base structure and the planarization layer comprises conformally depositing the spacer material using an atomic layer deposition (ALD) process.

14. The method of claim 12, wherein the dry etch process is an ion bombardment process.

15. The method of claim 12, wherein forming the spacer layer by using the wet etch process to remove the modified spacer material comprises submerging the electronic device in dilute hydrofluoric acid (dHF).

16. The method of claim 12, wherein the plurality of features has an aspect ratio of greater than or equal to about 10:1.

17. The method of claim 12, wherein the plurality of features has an associated critical dimension between about 10 nanometers (nm) to about 30 nm.

18. The method of claim 12, wherein the plurality of features has an associated critical dimension between about 15 nm to about 20 nm.

19. The method of claim 12, wherein the spacer material comprises a silicon-based dielectric material.

20. The method of claim 12, wherein the electronic device comprises a complementary field-effect transistor (cFET) device.
